(19) United States
(12) Patent Application Publication
(10) Pub. No.: US 2008/0242020 A1
(43) Pub. Date: Oct. 2, 2008

(54) METHOD OF MANUFACTURING A MOS TRANSISTOR DEVICE

(76) Inventors: Jei-Ming Chen, Taipei Hsien (TW); Neng-Kuo Chen, Hsin-Chu City (TW); Hsiu-Lien Liao, Tai-Chung City (TW); Teng-Chun Tsai, Hsin-Chu City (TW); Chien-Chung Huang, Tai-Chung Hsien (TW); Shih-Wei Sun, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/692,912

(22) Filed: Mar. 28, 2007

(51) Int. Cl. H01L 21/8238; H01L 21/336

(52) U.S. Cl. 438/233; 438/308; 257/E21.632; 257/E21.409

(57) ABSTRACT

A method of manufacturing a metal-oxide-semiconductor (MOS) transistor device is disclosed. A semiconductor substrate and a gate structure positioned on the semiconductor substrate are prepared first. A source region and a drain region are included in the semiconductor substrate on two opposite sides of the gate structure. Subsequently, a stressed cap layer is formed on the semiconductor substrate, and covers the gate structure, the source region and the drain region. Next, an inert gas treatment is performed to change a stress value of the stressed cap layer. Because the stress value of the stressed cap layer can be adjusted easily by means of the present invention, one stressed cap layer can be applied to both the N-type MOS transistor and the P-type MOS transistor.

### BACKGROUND OF THE INVENTION

1. Field of the Invention

The present invention generally relates to the field of forming metal-oxide-semiconductor (MOS) transistors, and more particularly, to a method for forming MOS transistors by utilizing a stressed cap layer having a binary-stress structure. From one aspect of the present invention, a stress value of parts of the stressed cap layer is changed by an inert gas treatment so that a drive current of the MOS transistor, and the performance of the MOS transistor can be developed.

2. Description of the Prior Art

Due to the hasty improvement of semiconductor manufacturing technology, the performance and the stability of the MOS transistor has become increasingly important. To fit the requirement, the MOS transistor devices, which have strained silicon (Si), have been proposed. As the silicon band structure alters, the carrier mobility increases. Consequently, the MOS transistor devices having strained silicon in its channel region typically enables a 1.5 to 8 times speed increase. The methods of forming the MOS transistor devices having strained silicon are substantially divided into two kinds. According to the first kind of methods, a biaxial tensile strain occurs in the silicon layer because the SiGe, which has a larger lattice constant than silicon, is grown in the silicon wafer. According to the second kind of methods, a stressed cap layer covers on the MOS transistor structure so that the stress of the stressed cap layer changes the lattice structure in the channel region of the MOS transistor device.

Please refer to FIGS. 1-3. FIGS. 1-3 are schematic cross-sectional diagrams illustrating a traditional method of fabricating a NMOS transistor device 10 and a PMOS transistor device 110. As shown in FIG. 1, a semiconductor substrate 16 is prepared, where a first transistor region 1 and a second transistor region 2 are defined therein. The first transistor region 1 is used to fabricate an NMOS device 10, while the second transistor region 2 is used to fabricate a PMOS device 110. The first transistor region 1 and the second transistor region 2 respectively include gate dielectric layers 14, 114 positioned on the semiconductor substrate 16, and gates 12, 112 positioned on the gate dielectric layers 14, 114. In general, the gates 12, 112 include polysilicon, and a gate and a gate dielectric layer can be named a gate structure. In the first transistor region 1, the semiconductor substrate 16 includes a source region 18 and a drain region 20 in the semiconductor substrate 16 and on the opposite sides of the gate 12. In the second transistor region 2, the semiconductor substrate 16 includes a source region 118 and a drain region 120 in the semiconductor substrate 16 and on the opposite sides of the gate 112. The source region 18 and the drain region 20 are separated by a channel region 22, while the source region 118 and a drain region 120 are separated by a channel region 122. Ordinarily, the source region 18 and drain region 20 further border a shallow-junction source extension 17 and a shallow-junction drain extension 19, respectively. The source region 118 and drain region 120 further border a shallow-junction source extension 117 and a shallow-junction drain extension 119, respectively.

In the device 10 illustrated in FIG. 1, the source region 18 and drain region 20 are N+ regions having been doped by arsenic, antimony or phosphorous. The channel region 22 is generally a P-type region. The source region 118 and drain region 120 are P+ regions having been doped by boron. The channel region 122 is generally an N-type region.

Silicon nitride spacers 32 and 132 are formed on sidewalls of the gates 12 and 112. A liner 30, generally comprising silicon dioxide, is interposed between the gate 12 and the spacer 32. A liner 130 is interposed between the gate 112 and the spacer 132. A salicide layer 42 is selectively formed on the exposed silicon surface of the devices 10 and 110, such as the gates 12, 112, the source regions 18, 118 and the drain regions 20, 120, so as to contact with the following-up contact plug holes. Fabrication of the NMOS transistor device 10 and the PMOS transistor device 110 illustrated in FIG. 1 is well known in the art and will not be discussed in detail herein.

As shown in FIG. 2, after forming the NMOS transistor device 10 and the PMOS transistor device 110 illustrated in FIG. 1, a stressed cap layer 46 including silicon nitride is deposited on the semiconductor substrate 16. The stressed cap layer 46 covers the salicide layer 42, spacers 32 and 132. The thickness of the stressed cap layer 46 is typically in the range of between 200 angstroms and 400 angstroms.

In one aspect, the stressed cap layer 46 is deposited to strain the channel region 22 of the NMOS transistor device 10 for changing the lattice of the channel region 22. In another aspect, the stressed cap layer 46 is formed so that there is an obvious etching stop for the following-up etching process of contact plug holes. In other words, the stressed cap layer 46 functions as a contact etch stop layer (CESL). After depositing the stressed cap layer 46, an anneal process is performed to enhance the stress of the stressed cap layer 46.

As shown in FIG. 3, a dielectric layer 48, such as a silicon oxide layer, is deposited over the stressed cap layer 46. The dielectric layer 48 is typically much thicker than the stressed cap layer 46. Subsequently, conventional lithographic and etching processes are carried out to form a plurality of contact holes 52 in the dielectric layer 48 and in the stressed cap layer 46. As aforementioned, the stressed cap layer 46 acts as an etching stop layer during the dry etching process to alleviate source/drain damages.

However, there are some drawbacks existing in the traditional technique. The stressed cap layer 46 is deposited across the whole wafer, making it harder to optimize the NMOS and PMOS transistors separately. That is to say, the tensile stress of the NMOS transistor device 10 and the tensile stress of the PMOS transistor device 110 are both enhanced. Although the performance of the NMOS transistor device 10 is improved, the performance of the PMOS transistor device 110 therefore decreases.

In order to benefit both the NMOS transistor device and the PMOS transistor device, another prior art technology named selective strain scheme (SSS) is adopted in processes of the stressed cap layer. Accordingly, a tensile-stressed cap layer is first deposited on the whole semiconductor substrate, covering the NMOS transistor device and the PMOS transistor device. Subsequently, a patterning process is preformed to remove parts of the tensile-stressed cap layer positioned on the PMOS transistor device. Thereafter, a compressive-stressed cap layer is deposited on the whole semiconductor substrate, covering the NMOS transistor device and the PMOS transistor device. Next, another patterning process is preformed to remove parts of the compressive-stressed cap layer positioned on the NMOS transistor device.

Even though the prior art SSS technology can benefit both the NMOS transistor device and the PMOS transistor device, the manufacturing process of the SSS technology is very complex. It not also takes a long time, but also has a huge cost. In addition, the complex process may cause more defects.

Thus, a need exists in this industry to provide an inexpensive method for making a MOS transistor device having improved functionality and performance.

### SUMMARY OF THE INVENTION

It is the primary object of the present invention to provide a method of manufacturing a MOS transistor devices having improved performance by utilizing a stressed cap layer having a binary-stress structure.

According to the claimed invention, a method of forming a MOS transistor device is disclosed. First, a semiconductor substrate, a gate dielectric layer positioned on the semiconductor substrate, and a gate positioned on the gate dielectric layer are provided. The semiconductor substrate comprises a source region and a drain region, and the source region and the drain region are positioned in the semiconductor substrate and on the opposite sides of the gate. Substantially, a stressed cap layer is formed on the semiconductor substrate. The stressed cap layer covers the gate, the source region and the drain region. Next, an inert gas treatment is performed to change a stress value of the stressed cap layer.

From one aspect of the present invention, a method of forming a MOS transistor device is provided. First, a semiconductor substrate is provided. A first transistor region and a second transistor region are defined in the semiconductor substrate. The first transistor region and the second transistor region respectively comprise a gate structure. The semiconductor substrate comprises a source region and a drain region on the opposite sides of each of the gate structures. Substantially, a stressed cap layer is formed on the semiconductor substrate in the first transistor region and in the second transistor region. The stressed cap layer covers the gate structures, the source regions and the drain regions. Next, an inert gas treatment is performed to change a stress value of the stressed cap layer in the second transistor region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are schematic cross-sectional diagrams illustrating a traditional method of fabricating a NMOS transistor device and a PMOS transistor device.

FIGS. 4-11 are schematic cross-sectional diagrams illustrating a method of fabricating a NMOS transistor device and a PMOS transistor device in accordance with a first preferred embodiment of the present invention.

FIGS. 12-17 are schematic cross-sectional diagrams illustrating a method of fabricating a NMOS transistor device and a PMOS transistor device in accordance with a second preferred embodiment of the present invention.

FIG. 18 is a schematic bar chart illustrating stress values of the silicon nitride cap layers in the present invention.

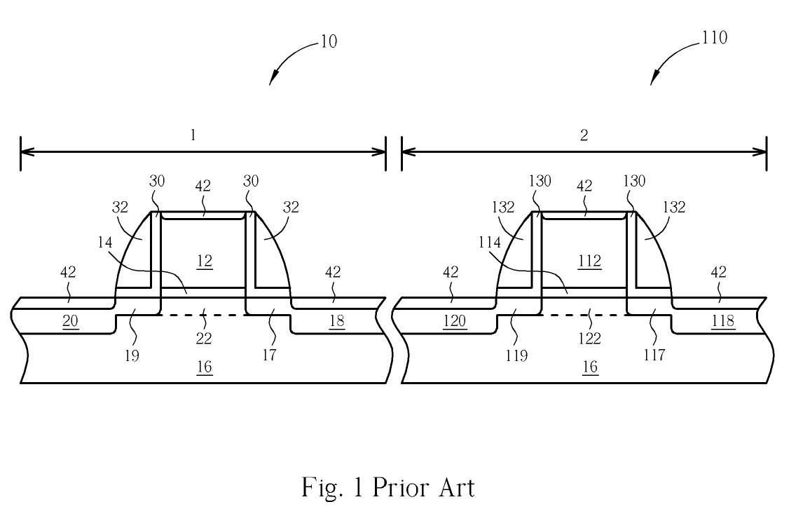

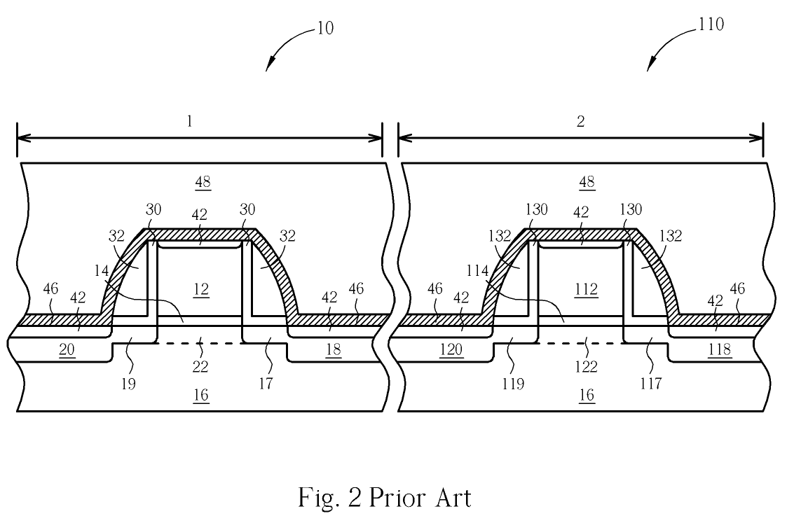

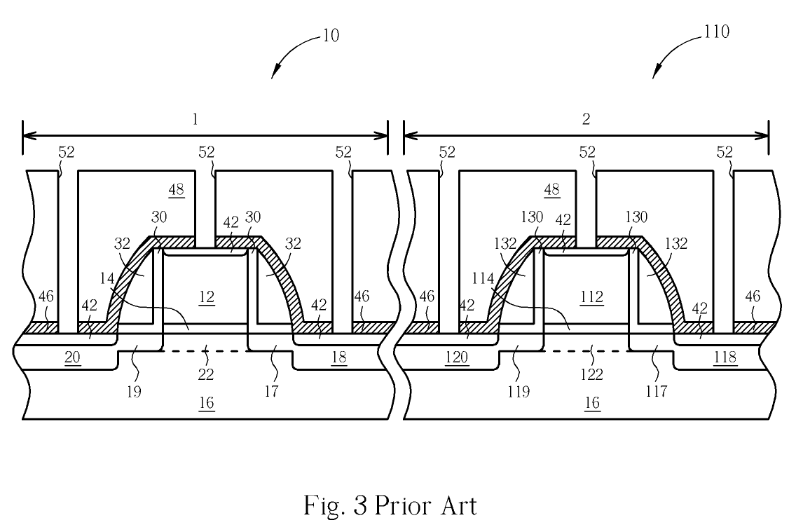

### DETAILED DESCRIPTION

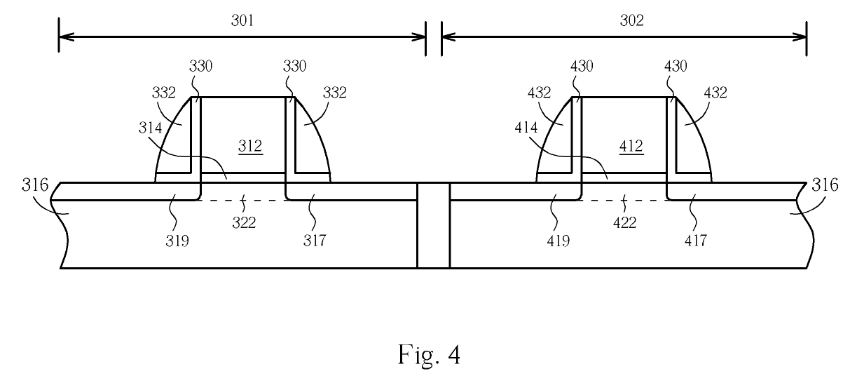

Please refer to FIGS. 4-11. FIGS. 4-11 are schematic cross-sectional diagrams illustrating a method of fabricating a NMOS transistor device 310 and a PMOS transistor device 410 in accordance with a first preferred embodiment of the present invention, wherein the same numerals designate similar or the same elements. The drawings are not drawn to scale and serve only for illustration purposes. In addition, it is to be understood that some lithographic and etching processes relating to the present invention method are known in the art and thus not explicitly shown in the drawings.

The present invention pertains to a method of fabricating MOS transistor devices having strained silicon or a CMOS transistor device having strained silicon. For example, a CMOS process is demonstrated through FIGS. 4-11. As shown in FIG. 4, a semiconductor substrate 316 is first prepared. A first transistor region 301 and a second transistor region 302 are defined in the semiconductor substrate 316. The first transistor region 301 is used to fabricate an NMOS device 310, while the second transistor region 302 is used to fabricate a PMOS device 410. According to this invention, the semiconductor substrate 316 may be a silicon substrate or a silicon-on-insulator (SOI) substrate, but is not limited thereto. First, a gate dielectric layer 314 is formed on the semiconductor substrate 316 in the first transistor region 301, and a gate 312 is formed on the gate dielectric layer 314 simultaneously. On the other hand, a gate dielectric layer 414 is formed on the semiconductor substrate 316 in the second transistor region 302, and a gate 412 is formed on the gate dielectric layer 414 simultaneously. The gate 312 and the gate dielectric layer 314 can be named a gate structure, and the gate 412 and the gate dielectric layer 414 are another gate structure. The gates 312 and 412 generally include a conductive material, such as polysilicon or salicide. The gate dielectric layers 314 and 414 may be made of silicon dioxide. However, in another embodiment of the present invention, the gate dielectric layers 314 and 414 may be made of other insulating materials, such as high-k materials.

Substantially, a shallow-junction source extension 317 and a shallow-junction drain extension 319 are formed in the semiconductor substrate 316 within the first transistor region 301 by means of utilizing the gate 312 as an implanting mask. The source extension 317 and drain extension 319 are separated by a channel region 322. Next, in second transistor region 302, a shallow-junction source extension 417 and a shallow-junction drain extension 419 are formed in the semiconductor substrate 316 and are separated by channel region 422.

Thereafter, by means of utilizing deposition processes and an etch-back process, silicon nitride spacers 332 and 432 are formed on respective sidewalls of the gates 312 and 412, and liners 330 and 430 are formed in the meantime between the spacers and the gates respectively. The liners 330 and 430 are typically L-shaped, including silicon dioxide, and have a thickness about 30 angstroms to 120 angstroms. In addition, in other embodiments of the present invention, the liner 330 and the liner 430 may be offset spacers.

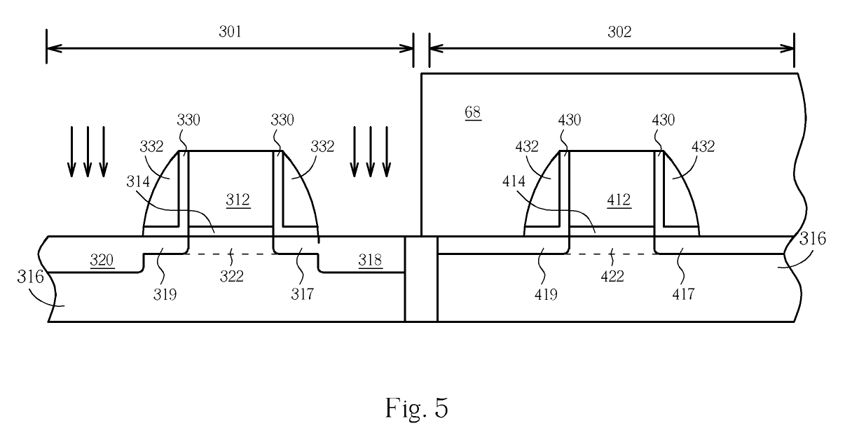

As shown in FIG. 5, after forming the spacers 332 and 432, a mask layer 68 such as a photoresist layer is formed to mask the second transistor region 302 only. An ion implantation process is carried out to dope N-type dopant species, such as arsenic, antimony or phosphorous, into the semiconductor substrate 316 within the first transistor region 301, thereby forming a source region 318 and a drain region 320. The mask layer 68 is then stripped off.

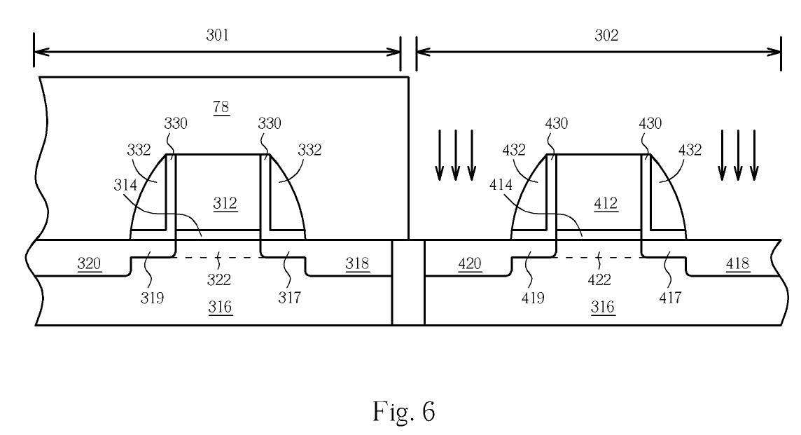

As shown in FIG. 6, a mask layer 78 is formed to cover the first transistor region 301. Another ion implantation process is thereafter carried out to dope P-type dopant species, such as boron, into the semiconductor substrate 316 within the second transistor region 302, thereby forming a source region 418 and a drain region 420. The mask layer 78 is then stripped off after performing the ion implantation process. It is to be understood that the sequence as set forth in FIG. 5 and FIG. 6 may be reversed. In other words, the P-type doping process for the second transistor region 302 may be carried out first, and then the N-type doping process for the first transistor region 301 is performed. After doping the source regions 318, 418 and the drain regions 320, 420, the semiconductor substrate 316 may further be subjected to an annealing and/or activation thermal process that is known in the art.

In addition, it should be understood by a person skilled in this art that a selective epitaxial growth process (SEG process) could be integrated in the present invention to grow a silicon germanium (SiGe) layer or a silicon carbon (SiC) layer in the semiconductor substrate as a source region and a drain region.

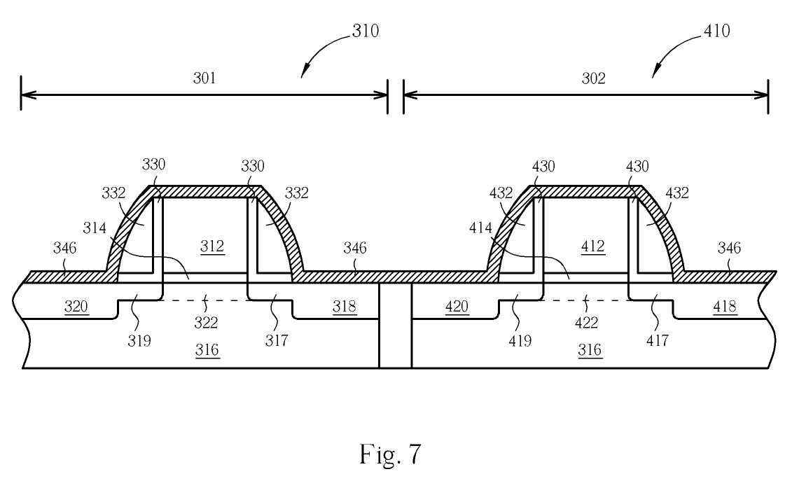

As shown in FIG. 7, in accordance with the preferred embodiment, a stressed cap layer 346 is deposited on the semiconductor substrate 316, and the stressed cap layer 346 will function as a poly stressor in the processes. The stressed cap layer 346 borders the source regions 318, 418, the drain regions 320, 420, and the gates 312, 412. The thickness of the stressed cap layer 346 is about 30 angstroms to 2000 angstroms. The stressed cap layer 346 is initially deposited in a tensile-stressed status, and the as-deposition stress value is about 0.5 Giga-pascals (GPa) to 2.5 GPa. Afterward, a surface treatment, such as a UV curing process, a thermal spike anneal process, a laser anneal process or an e-beam treatment, can be performed to the stressed cap layer 346 so as to enhance the stress value of the stressed cap layer 346.

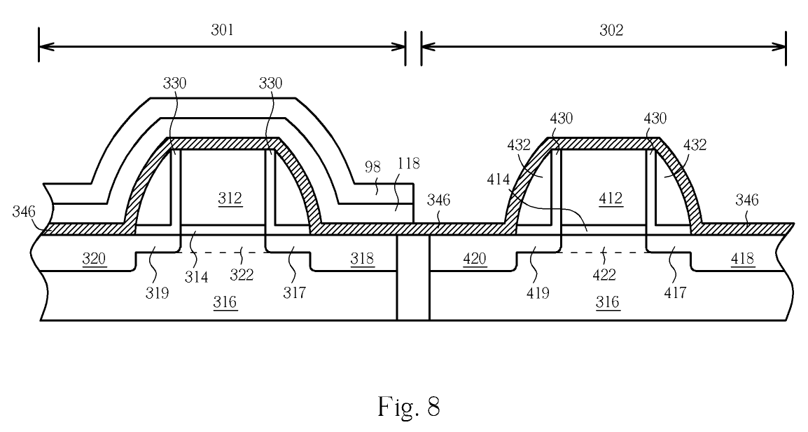

As shown in FIG. 8, furthermore, a mask layer is evenly deposited on the semiconductor substrate 316, covering the stressed cap layer 346. The mask layer is made of materials which have a better selective etching ratio to the stressed cap layer 346. In this embodiment, the mask layer can be made of oxide, or include both oxide and photoresist. Moreover, a patterning process is preformed by means of utilizing a photoresist 98 as an etching mask to remove parts of the mask layer positioned within the second transistor region 302 so as to form a patterned hard mask 188. Accordingly, the patterned hard mask 188 covers parts of the stressed cap layer 346 positioned in the first transistor region 301, and exposes parts of the stressed cap layer 346 positioned in the second transistor region 302. In other embodiments, the patterned hard mask 188 can be directly made of photoresist with a proper thickness so that the step of fabricating the photoresist 98 can be omitted.

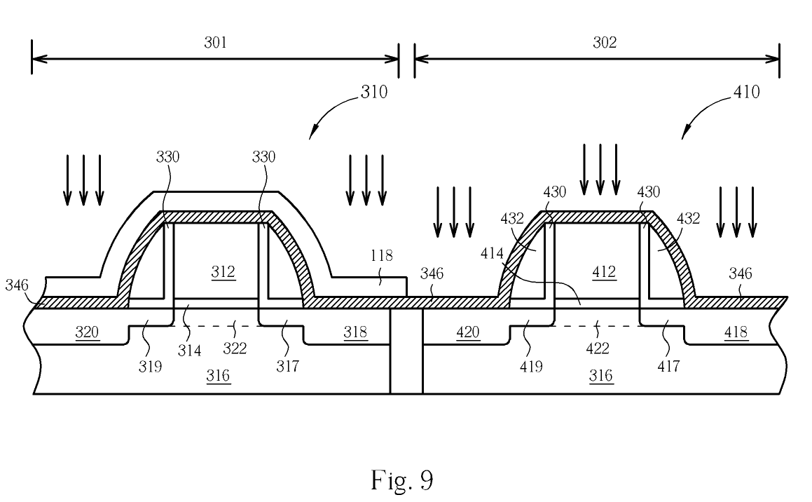

Next, as shown in FIG. 9, the photoresist 98 is removed, and an inert gas treatment is thereafter performed to change a stress value of parts of the stressed cap layer 346, which are not covered by the patterned hard mask 188. The inert gas treatment can be performed in a chemical vapor deposition (CVD) machine, or in a physical vapor deposition (PVD) machine. The inert gas treatment is performed by utilizing argon (Ar) and other inert gases, and a treatment power of the inert gas treatment has a range from 0.1 kilo-watts (KW) to 10 KW. In other embodiments, the inert gas treatment may use one or more then one gas selected from the group of helium (He), krypton (Kr), nitride, oxide or other inert gases.

The inert gas treatment can greatly release the tensile stress value of the stressed cap layer 346, which are not covered by the patterned hard mask 188. By means of adjusting the process factors, such as the treatment power or the treatment time, the stress value of the stressed cap layer 346 can be adjusted by the present invention. In other words, the stressed cap layer 346 covering the semiconductor substrate 316 has a binary-stress structure after performing the inert gas treatment. That is to say, the stressed cap layer 346 covering the NMOS transistor device 310 has a larger tensile stress value, and the stressed cap layer 346 covering the PMOS transistor device 410 has a smaller tensile stress value. By means of adjusting the process factors, such as increasing the treatment power or increasing the treatment time, the stress value of the stressed cap layer 346 can be more released. The tensile stress value of the stressed cap layer 346 covering the PMOS transistor device 410 can even be removed.

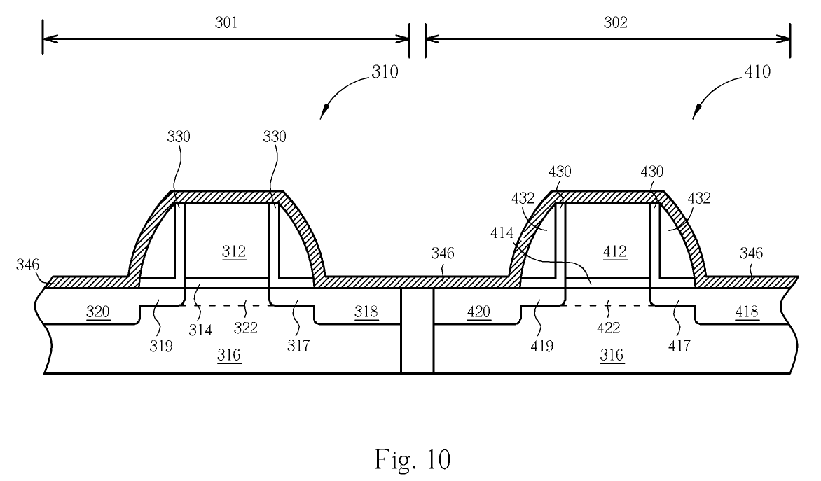

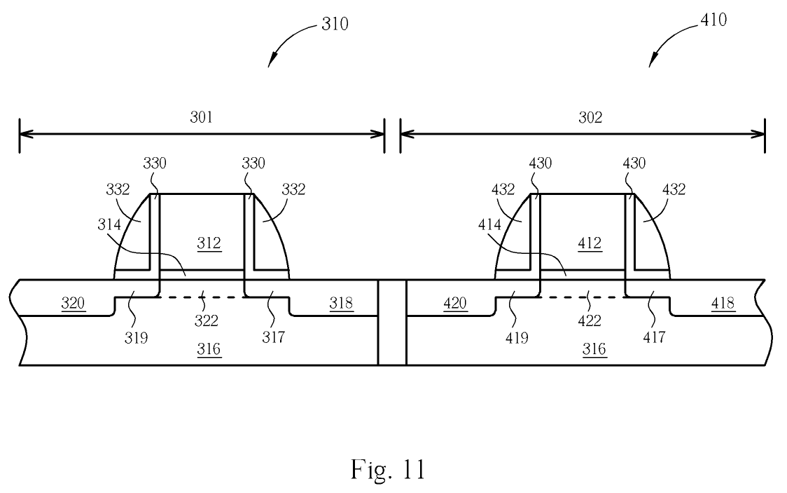

As shown in FIG. 10, the patterned hard mask 188 is removed, and a rapid thermal process (RTP) is thereafter performed to memory the stress status of the stressed cap layer 346 into the NMOS transistor device 310 and into the PMOS transistor device 410. Next, as shown in FIG. 11, the stressed cap layer 346 is removed, and a CMOS transistor device having strained silicon is formed.

After forming the above-mentioned CMOS transistor device, other MOS processes, such as a salicide process, a dielectric layer deposition process, and a contact hole etching process, can be further performed as known by a person skilled in this art.

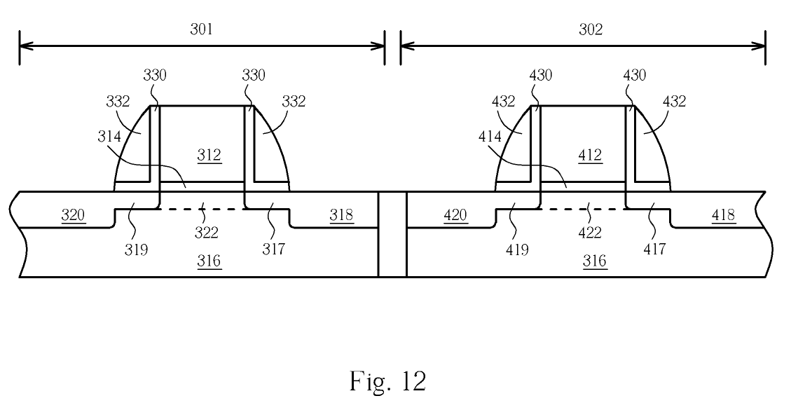

Please refer to FIGS. 12-17. FIGS. 12-17 are schematic cross-sectional diagrams illustrating a method of fabricating a NMOS transistor device 310 and a PMOS transistor device 410 in accordance with a second preferred embodiment of the present invention, wherein the same numerals designate similar or the same elements. As shown in FIG. 12, a semiconductor substrate 316 is first prepared. A first transistor region 301 and a second transistor region 302 are defined in the semiconductor substrate 316. First, within the first transistor region 301, a gate dielectric layer 314 positioned on the semiconductor substrate 316, a gate 312 positioned on the gate dielectric layer 314, and a source region 318 and a drain region 320 positioned on the opposite sides of the gate 312 are included. The source region 318 and drain region 320 are separated by a N-type channel region 322. On the other hand, within the second transistor region 302, a gate dielectric layer 414 positioned on the semiconductor substrate 316, a gate 412 positioned on the gate dielectric layer 414, and a source region 418 and a drain region 420 positioned on the opposite sides of the gate 412 are included. The source region 418 and drain region 420 are separated by a P-type channel region 422. Additionally, a liner 330 and a spacer 332 are included on respective sidewalls of the gate 312, and a liner 430 and a spacer 432 are included on respective sidewalls of the gate 412.

Similarly, an SEG process could be selectively integrated in the present invention to grow a silicon germanium layer or a silicon carbon layer in the semiconductor substrate as a source region and a drain region.

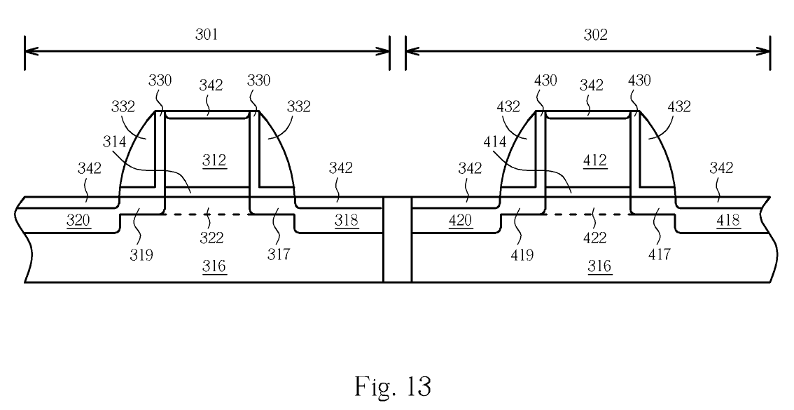

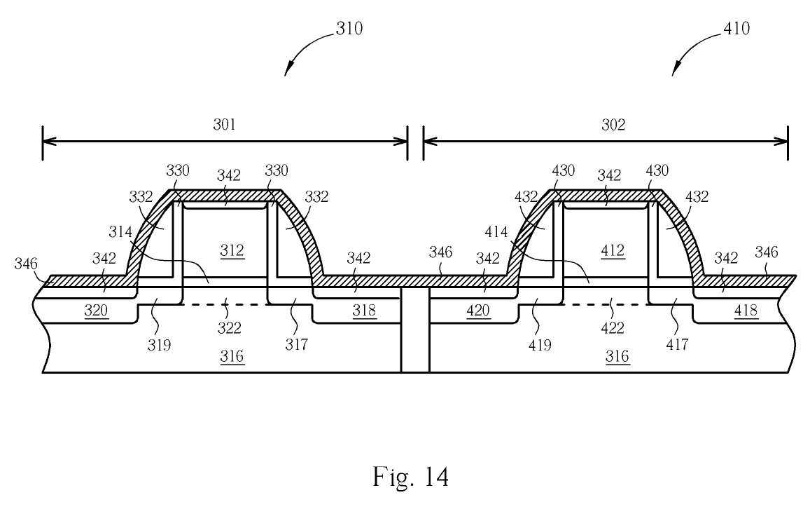

As shown in FIG. 13, a salicide process is thereafter performed to form a salicide layer 342, such as a nickel salicide layer, on the source regions 318, 418, the drain regions 320, 420, and the gates 312, 412. Subsequently, as shown in FIG. 14, a stressed cap layer 346 is deposited on the semiconductor substrate 316 evenly. The stressed cap layer 346 borders the source regions 318, 418, the drain regions 320, 420, and the gates 312, 412. The stressed cap layer 346 is initially deposited in a tensile-stressed status, and the as-deposition stress value is about 0.5 GPa to 2.5 GPa. Afterward, a surface treatment, such as a UV curing process, a thermal spike anneal process, a laser anneal process or an e-beam treatment, can be performed to the stressed cap layer 346 so as to enhance the stress value of the stressed cap layer 346.

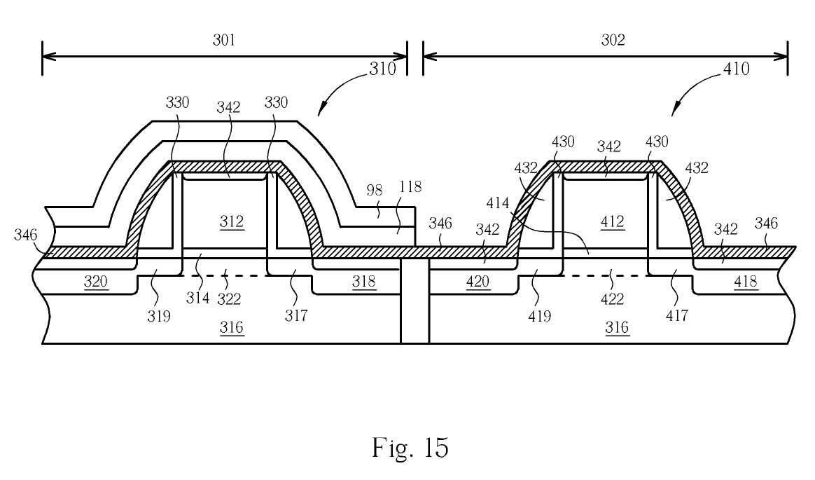

As shown in FIG. 15, furthermore, a mask layer is evenly deposited on the semiconductor substrate 316, covering the stressed cap layer 346. The mask layer can be made of materials, which have a better selective etching ratio to the stressed cap layer 346. For example, the mask layer can be made of oxide, photoresist, or include both oxide and photoresist. Moreover, a patterning process is preformed by means of utilizing a photoresist 98 as an etching mask to remove parts of the mask layer positioned within the second transistor region 302 so as to form a patterned hard mask 188. Accordingly, the patterned hard mask 188 covers parts of the stressed cap layer 346 positioned in the first transistor region 301, and exposes parts of the stressed cap layer 346 positioned in the second transistor region 302.

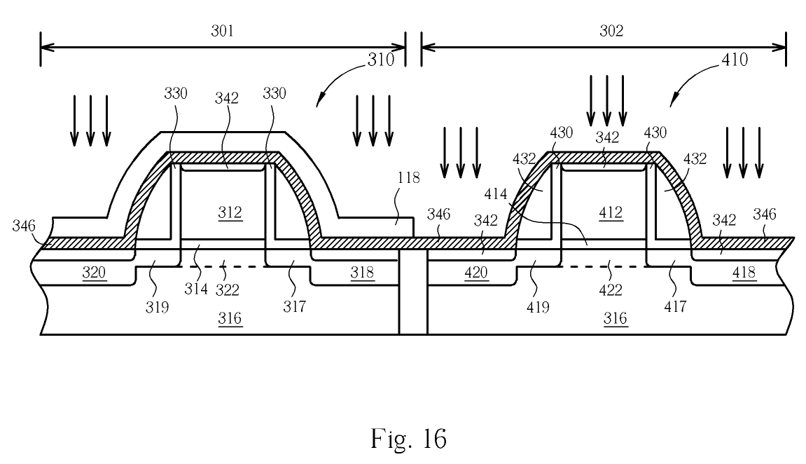

Next, as shown in FIG. 16, the photoresist 98 is removed, and an inert gas treatment is thereafter performed to change a stress value of parts of the stressed cap layer 346, which are not covered by the patterned hard mask 188. The inert gas treatment can be performed in a CVD machine, or in a PVD machine. The inert gas treatment is performed by utilizing argon (Ar) and other inert gases, and a treatment power of the inert gas treatment has a range from 0.1 KW to 10 KW.

The inert gas treatment can greatly release the tensile stress value of the stressed cap layer 346, which are not covered by the patterned hard mask 188. In other words, the stressed cap layer 346 covering the NMOS transistor device 310 has a larger tensile stress value, and the stressed cap layer 346 covering the PMOS transistor device 410 has a smaller tensile stress value, or even has a stress value about zero.

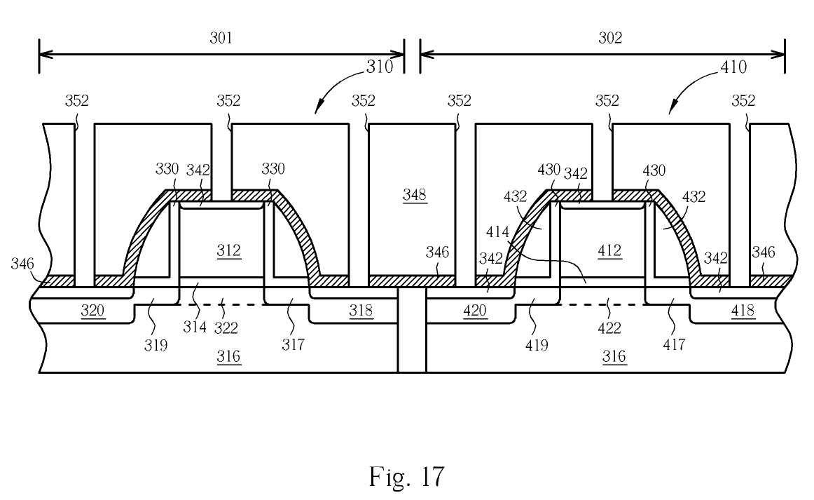

As shown in FIG. 17, the patterned hard mask 188 is removed, and a dielectric layer 348 is thereafter deposited over the first transistor region 301 and the second transistor region 302 on the stressed cap layer 346. The dielectric layer 348 may be made of silicon oxide, doped silicon oxide or other suitable materials such as low-k materials. According to another embodiment of this invention, the dielectric layer 48 may have stress therein. Lithographic and etching processes are then carried out to form contact holes 352 in the dielectric layer 348 and in the silicon nitride cap layer 346. The contact holes 52 communicate with the source regions 318, 418, the drain regions 320, 420, and the gates 312, 412. In another embodiment, contact holes may be formed to communicate with only the source regions 318, 418, and the drain regions 320, 420 (not shown in the figures). From one aspect of the present invention, the silicon nitride cap layer 46 functions as a contact etch stop layer during the dry etching of the contact holes 52 for alleviating surface damages.

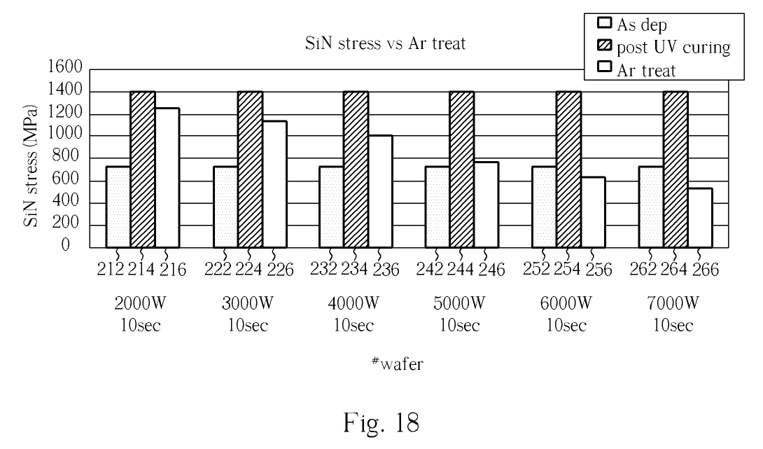

Please refer to FIG. 18. FIG. 18 is a schematic bar chart illustrating stress values of the silicon nitride cap layers 346 in the present invention, where the vertical coordinate axis shows the tensile stress values. The chart shows six groups of the stress values of the silicon nitride cap layers, and the silicon nitride cap layer in each group is measured for at least three times. The values 212, 222, 232, 242, 252, and 262 are the as-deposition stress values of the silicon nitride cap layers. The values 214, 224, 234, 244, 254, and 264 are the stress values of the silicon nitride cap layers, which have been undergone the UV curing process. The values 216, 226, 236, 246, 256, and 266 are the stress values of the silicon nitride cap layers, which have been undergone the inert gas treatment. The differences among the six groups lie in the treatment powers of the inert gas treatments. The treatment powers of the inert gas treatments of the six groups are 2 KW, 3 KW, 4 KW, 5 KW, 6 KW and 7 KW from left to right respectively. As shown in FIG. 18, the larger the treatment power is, the more the tensile stress value releases. When the treatment power of the inert gas treatment is larger than 5 KW, the tensile stress value of the stressed cap layer after the inert gas treatment can even be lower than the as-deposition stress value of the stressed cap layer. The treatment times of the inert gas treatments are all 10 seconds in the above-mentioned six groups, but the treatment time should not be limited to 10 seconds.

From one characteristic of the present invention, a stress value of parts of the stressed cap layer can be changed by an inert gas treatment so that the stressed cap layer has a binary-stress structure. As a result, parts of the stressed cap layer having a high tensile stress can change the lattice structure in the channel region of the NMOS transistor device. Accordingly, a drive current of the NMOS transistor and the performance of the NMOS transistor can be developed. On the other hand, parts of the stressed cap layer covering the PMOS transistor device have a smaller tensile stress value, and the performance of the PMOS transistor can be protected from being decreasing by the stressed cap layer. In summary, the drive currents and the performances can be developed for both the NMOS transistor device and the PMOS transistor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a MOS transistor device, comprising:
providing a semiconductor substrate, a gate dielectric layer positioned on the semiconductor substrate, and a gate positioned on the gate dielectric layer, the semiconductor substrate comprising a source region and a drain region, the source region and the drain region positioned in the semiconductor substrate and on the opposite sides of the gate;
forming a stressed cap layer on the semiconductor substrate, covering the gate, the source region and the drain region; and
performing an inert gas treatment to change a stress value of the stressed cap layer.

2. The method of forming a MOS transistor device according to claim 1, wherein the MOS transistor device is an NMOS transistor device.

3. The method of forming a MOS transistor device according to claim 1, wherein the MOS transistor device is a PMOS transistor device.

4. The method of forming a MOS transistor device according to claim 1, wherein the stressed cap layer comprises silicon nitride.

5. The method of forming a MOS transistor device according to claim 1, wherein the stressed cap layer comprises a tensile stress before performing the inert gas treatment.

6. The method of forming a MOS transistor device according to claim 5, wherein the inert gas treatment is performed for releasing the tensile stress of the stressed cap layer.

7. The method of forming a MOS transistor device according to claim 5, wherein the tensile stress of the stressed cap layer before the inert gas treatment has a range from 0.5 Giga pascals (GPa) to 2.5 GPa.

8. The method of forming a MOS transistor device according to claim 1, wherein the inert gas treatment is performed in a chemical vapor deposition (CVD) machine.

9. The method of forming a MOS transistor device according to claim 1, wherein the inert gas treatment is performed in a physical vapor deposition (PVD) machine.

10. The method of forming a MOS transistor device according to claim 1, wherein the inert gas treatment comprises argon (Ar) and other inert gases.

11. The method of forming a MOS transistor device according to claim 1, wherein a treatment power of the inert gas treatment has a range from 0.1 kilo-watts (KW) to 10 KW.

12. The method of forming a MOS transistor device according to claim 1, further comprising an UV curing process, a thermal spike anneal process, a laser anneal process or an e-beam treatment after forming the stressed cap layer.

13. The method of forming a MOS transistor device according to claim 1, further comprising a rapid thermal process (RTP) after performing the inert gas treatment.

14. The method of forming a MOS transistor device according to claim 13, further comprising a step of removing the stressed cap layer after performing the rapid thermal process.

15. The method of forming a MOS transistor device according to claim 1, further comprising a step of forming a salicide layer on the source region and the drain region.

16. The method of forming a MOS transistor device according to claim 15, wherein the stressed cap layer functions as a contact etch stop layer (CESL) during a step of etching a contact plug hole.

17. The method of forming a MOS transistor device according to claim 1, wherein the gate comprises a liner on two sidewalls of the gate.

18. The method of forming a MOS transistor device according to claim 17, wherein the gate comprises a spacer adjacent to the liner.

19. The method of forming a MOS transistor device according to claim 1, further comprising a step of forming a source extension and a drain extension in the semiconductor substrate.

20. A method of forming a MOS transistor device, comprising:
providing a semiconductor substrate, a first transistor region and a second transistor region being defined in the semiconductor substrate, the first transistor region and the second transistor region respectively comprising a gate structure, the semiconductor substrate comprising a source region and a drain region on the opposite sides of each of the gate structures;
forming a stressed cap layer on the semiconductor substrate in the first transistor region and in the second transistor region, the stressed cap layer covering the gate structures, the source regions and the drain regions; and
performing an inert gas treatment to change a stress value of the stressed cap layer in the second transistor region.

21. The method of forming a MOS transistor device according to claim 20, further comprising a step of forming a patterned hard mask on the stressed cap layer before performing the inert gas treatment, wherein the patterned hard mask covers parts of the stressed cap layer positioned in the first transistor region, and exposes parts of the stressed cap layer positioned in the second transistor region.

22. The method of forming a MOS transistor device according to claim 20, wherein the MOS transistor device is a CMOS transistor device comprising an NMOS transistor and a PMOS transistor, the NMOS transistor is positioned in the first transistor region, and the PMOS transistor is positioned in the second transistor region.

23. The method of forming a MOS transistor device according to claim 20, wherein the stressed cap layer comprises silicon nitride.

24. The method of forming a MOS transistor device according to claim 21, wherein the patterned hard mask comprises oxide.

25. The method of forming a MOS transistor device according to claim 20, wherein a tensile stress of the stressed cap layer before the inert gas treatment has a range from 0.5 GPa to 2.5 GPa.

26. The method of forming a MOS transistor device according to claim 25, wherein the inert gas treatment is performed for releasing the tensile stress of the stressed cap layer.

27. The method of forming a MOS transistor device according to claim 20, wherein the inert gas treatment comprises argon and other inert gases.

28. The method of forming a MOS transistor device according to claim 20, further comprising an UV curing process, a thermal spike anneal process, a laser anneal process or an e-beam treatment after forming the stressed cap layer.

29. The method of forming a MOS transistor device according to claim 20, further comprising a rapid thermal process after performing the inert gas treatment.

30. The method of forming a MOS transistor device according to claim 29, further comprising a step of removing the stressed cap layer after performing the rapid thermal process.

31. The method of forming a MOS transistor device according to claim 20, further comprising a step of forming a salicide layer on the source region and the drain region.

32. The method of forming a MOS transistor device according to claim 31, wherein the stressed cap layer functions as a contact etch stop layer during a step of etching a contact plug hole.
